(19) United States
(12) Patent Application Publication
(10) Pub. No.: US 2015/0070964 A1
(43) Pub. Date: Mar. 12, 2015

(54) SEMICONDUCTOR MEMORY DEVICE AND METHOD OF OPERATING THE SAME

(71) Applicant: Kabushiki Kaisha Toshiba, Minato-ku (JP)

(72) Inventors: Yuki YAMADA, Mie (JP); Yoshiaki Asao, Mie (JP)

(73) Assignee: Kabushiki Kaisha Toshiba, Minato-ku (JP)

(21) Appl. No.: 14/166,057

(22) Filed: Jan. 28, 2014

(30) Foreign Application Priority Data
Sep. 11, 2013 (JP) 2013-188368

(51) Int. Cl. G11C 11/22; H01L 27/105

(52) U.S. Cl. CPC G11C 11/223; H01L 27/1052
USPC 365/145; 257/295

(57) ABSTRACT

A semiconductor memory device according to an embodiment includes a semiconductor layer, a gate electrode, a ferroelectric film provided between the semiconductor layer and the gate electrode, a first impurity region of a first conductivity type provided on one side of the gate electrode in the semiconductor layer, a second impurity region of a second conductivity type provided on the other side of the gate electrode in the semiconductor layer, a third impurity region of the first conductivity type provided between the first impurity region and the second impurity region in the semiconductor layer facing the gate electrode and having a lower first-conductivity-type impurity concentration than the first impurity region, a first wiring connected to the first impurity region through a connection portion contacting with the first impurity region, and a second wiring connected to the second impurity region through a connection portion contacting with the second impurity region.

### CROSS-REFERENCE TO RELATED APPLICATION

This application is based upon and claims the benefit of priority from Japanese Patent Application No. 2013-188368, filed on Sep. 11, 2013, the entire contents of which are incorporated herein by reference.

### FIELD

Embodiments described herein relate generally to a semiconductor memory device and a method of operating the same.

### BACKGROUND

There are many reports on non-volatile memories using ferroelectric films, that is, ferroelectric memories. The ferroelectric memories include a one-transistor/one-capacitor (1T1C) memory in which a memory cell includes one transistor for selecting a cell and one ferroelectric capacitor for holding data and a one-transistor (1T) memory in which a memory cell includes one transistor having a ferroelectric film as a gate insulating film.

The one-transistor (1T) memory in which the memory cell includes one transistor is suitable to reduce a memory size and increase memory capacity.

Therefore, there is a market demand for a ferroelectric random access memory in which data can be written and read to and from each cell.

### BRIEF DESCRIPTION OF THE DRAWINGS

FIGS. 1A to 1C are cross-sectional views schematically illustrating a semiconductor memory device according to a first embodiment;

FIG. 2 is a layout diagram illustrating the semiconductor memory device according to the first embodiment;

FIG. 3 is a circuit diagram illustrating the semiconductor memory device according to the first embodiment;

FIGS. 4A and 4B are diagrams illustrating a writing operation of the semiconductor memory device according to the first embodiment;

FIG. 5 is a diagram illustrating a reading operation of the semiconductor memory device according to the first embodiment;

FIGS. 6A to 6C are cross-sectional views schematically illustrating the semiconductor memory device according to the comparative embodiment;

FIG. 7 is a layout diagram illustrating the semiconductor memory device according to the comparative embodiment;

FIG. 8 is a circuit diagram illustrating the semiconductor memory device according to the comparative embodiment;

FIGS. 9A and 9B are diagrams illustrating a writing operation of the semiconductor memory device according to the comparative embodiment;

FIG. 10 is a diagram illustrating a reading operation of the semiconductor memory device according to the comparative embodiment;

FIGS. 11A to 11C are cross-sectional views schematically illustrating a semiconductor memory device according to a second embodiment;

FIG. 12 is a layout diagram illustrating the semiconductor memory device according to the second embodiment;

FIG. 13 is a circuit diagram illustrating the semiconductor memory device according to the second embodiment;

FIGS. 14A and 14B are diagrams illustrating a writing operation of the semiconductor memory device according to the second embodiment;

FIG. 15 is a diagram illustrating a reading operation of the semiconductor memory device according to the second embodiment;

FIGS. 16A to 16C are cross-sectional views schematically illustrating a semiconductor memory device according to a third embodiment;

FIGS. 17A and 17B are cross-sectional views schematically illustrating a semiconductor memory device according to a fourth embodiment;

FIG. 18 is a layout diagram illustrating a semiconductor memory device according to a fifth embodiment; and

FIGS. 19A and 19B are cross-sectional views schematically illustrating the semiconductor memory device according to the fifth embodiment.

### DETAILED DESCRIPTION

A semiconductor memory device according to an embodiment includes a semiconductor layer, a gate electrode, a ferroelectric film provided between the semiconductor layer and the gate electrode, a first impurity region of a first conductivity type provided on one side of the gate electrode in the semiconductor layer, a second impurity region of a second conductivity type provided on the other side of the gate electrode in the semiconductor layer, a third impurity region of the first conductivity type provided between the first impurity region and the second impurity region in the semiconductor layer facing the gate electrode and having a lower first-conductivity-type impurity concentration than the first impurity region, a first wiring connected to the first impurity region through a connection portion contacting with the first impurity region, and a second wiring connected to the second impurity region through a connection portion contacting with the second impurity region.

Hereinafter, an example in which a first conductivity type is n-type and a second conductivity type is p-type will be described.

### First Embodiment

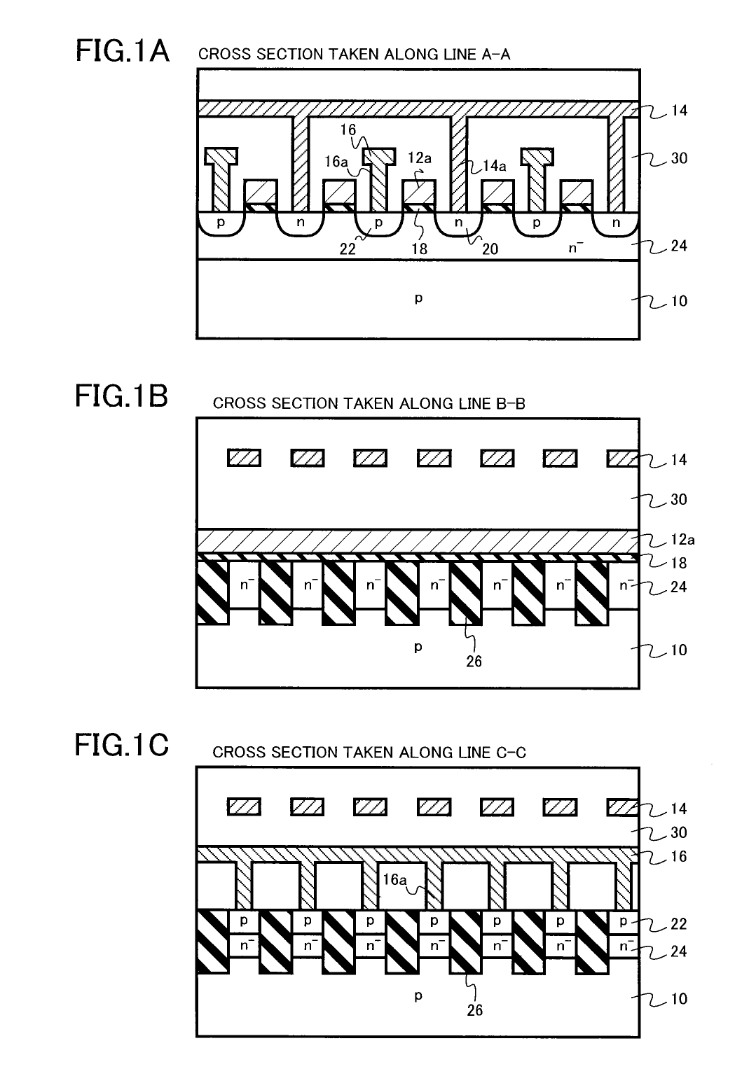

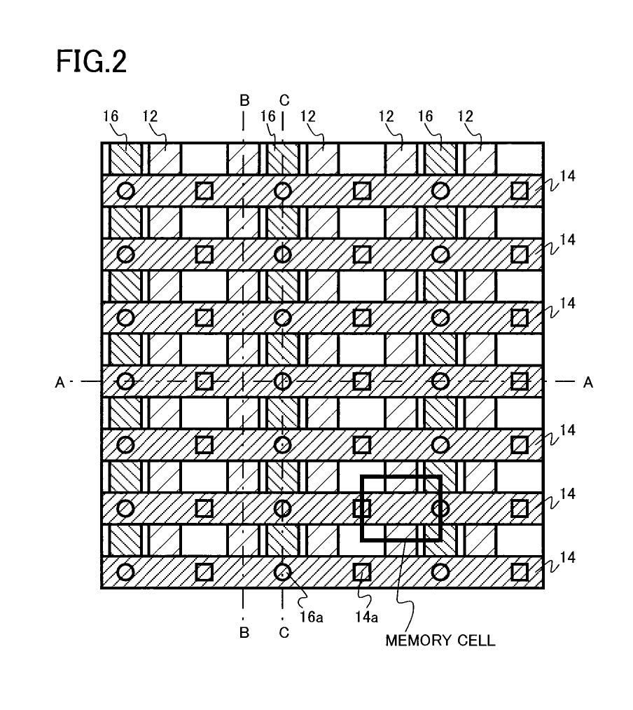

FIGS. 1A to 1C are cross-sectional views schematically illustrating the semiconductor memory device according to this embodiment. FIG. 2 is a layout diagram illustrating the semiconductor memory device according to this embodiment.

FIG. 2 is a top view illustrating a region of a memory cell array. FIG. 1A is a cross-sectional view taken along the line A-A of FIG. 2, FIG. 1B is a cross-sectional view taken along the line B-B of FIG. 2, and FIG. 1C is a cross-sectional view taken along the line C-C of FIG. 2.

As illustrated in FIG. 2, a plurality of memory cells are arranged in a matrix. In FIG. 2, a region surrounded by a thick frame indicates a memory cell, that is, a unit cell.

The semiconductor memory device according to this embodiment includes a plurality of word lines (gate electrode lines) 12, a plurality of bit lines (first wirings) 14, and a plurality of plate lines (second wirings) 16. A predetermined voltage is applied to the gate electrode lines 12, the bit lines 14, and the plate lines 16 in order to write, read, or erase data stored in each memory cell.

The plate line (second wiring) 16 extends in a direction parallel to the word line 12. In addition, the bit line (first wiring) 14 extends in a direction perpendicular to the word line 12.

The gate electrode line 12, the bit line 14, and the plate line 16 are made of a conductive material, such as metal, a metal semiconductor compound, or a semiconductor.

The semiconductor memory device according to this embodiment is formed on a semiconductor substrate (semiconductor layer) 10. The semiconductor substrate is, for example, a p-type silicon substrate.

Each memory cell includes a gate electrode 12a, a ferroelectric film 18, an n-type drain region (first impurity region) 20, a p-type source region (second impurity region) 22, and an n-type channel region (third impurity region) 24.

The gate electrode 12a is connected to one of a plurality of word lines (gate electrode lines) 12. The gate electrode 12a is made of, for example, a stacked film of titanium nitride (TiN) and amorphous silicon (α-Si). The gate electrode 12a may be made of a conductive material, such as metal, a metal semiconductor compound, or a semiconductor, other than the above-mentioned material.

The gate electrode 12a and the word line 12 may be formed in the same layer or different layers. In this embodiment, they are formed in the same layer.

The ferroelectric film 18 is provided between the semiconductor substrate (semiconductor layer) 10 and the gate electrode 12a. The ferroelectric film 18 functions as a gate insulating film of a transistor. The ferroelectric film 18 is made of, for example, hafnium oxide (HfO), zirconium oxide (ZrO), or aluminum oxide (AlO) having ferroelectricity. The ferroelectric film 18 can be made of other materials, such as PZT and SBT, as long as the materials have ferroelectricity.

In addition, a paraelectric film may be provided between the ferroelectric film 18 and the semiconductor substrate 10 or the gate electrode 12a to form a gate insulating film with a stacked structure. For example, a silicon oxide film is provided between the ferroelectric film 18 and the semiconductor substrate 10.

The n-type drain region (first impurity region) 20 is provided on one side of the gate electrode 12a in the surface of the semiconductor substrate (semiconductor layer) 10. The n-type drain region 20 includes, for example, arsenic (As) as n-type impurities.

The p-type source region (second impurity region) 22 is provided on the other side of the gate electrode 12a in the surface of the semiconductor substrate (semiconductor layer) 10. The p-type source region 22 includes, for example, boron (B) as p-type impurities.

The n-type channel region (third impurity region) 24 is provided in the surface of the semiconductor substrate (semiconductor layer) 10 so as to face the gate electrode 12a. The n-type channel region 24 is interposed between the n-type drain region (first impurity region) 20 and the p-type source region (second impurity region) 22. The concentration of n-type impurities in the n-type channel region 24 is lower than that in the n-type drain region 20. The n-type channel region 24 includes, for example, arsenic (As) or phosphorus (P) as n-type impurities.

An device isolation region 26, which is an insulator, is provided in the semiconductor substrate (semiconductor layer) 10. The device isolation region 26 is, for example, a silicon oxide film. The device isolation region 26 is formed so as to extend in the same direction as that in which the bit line 14 extends.

The n-type drain region (first impurity region) 20, the p-type source region (second impurity region) 22, and the n-type channel region (third impurity region) 24 are interposed between the device isolation regions 26. It is preferable that the depth of the n-type channel region 24 be less than that of the device isolation region 26 in order to maintain sufficient device isolation breakdown voltage.

A bit line connection portion 14a comes into contact with the n-type drain region (first impurity region) 20 and the n-type drain region 20 is connected to one of the plurality of bit lines (first wirings) 14 through the bit line connection portion 14a. A region in which the bit line connection portion 14a is formed is represented by a solid square in FIG. 2. The bit line connection portion 14a and the bit line 14 may be formed in the same layer or different layers. In this embodiment, they are formed in the same layer.

A plate line connection portion 16a comes into contact with the p-type source region (second impurity region) 22 and the p-type source region 22 is connected to one of the plurality of plate lines 16 through the plate line connection portion 16a. A region in which the plate line connection portion 16a is formed is represented by a solid circle in FIG. 2. The plate line connection portion 16a and the plate line 16 may be formed in the same layer or different layers. In this embodiment, they are formed in the same layer.

In addition, a p-well region which is deeper than the channel region 24 and the device isolation region 26 may be formed in the semiconductor substrate 10. When the p-well region is provided, for example, it is possible to electrically separate the memory cells from a peripheral circuit which is provided outside the memory cell array.

An interlayer insulating layer 30 is provided between the word lines 12, the bit lines 14, and the plate lines 16. The interlayer insulating layer 30 is, for example, a silicon oxide film.

In the semiconductor memory device according to this embodiment, as illustrated in FIGS. 1A to 1C and FIG. 2, the bit line connection portion 14a which connects the bit line (first wiring) 14 and the drain region (first impurity region) 20 is shared between two memory cells that are adjacent to each other in the direction in which the bit line 14 extends. In addition, the plate line connection portion 16a which connects the plate line (second wiring) 16 and the source region (second impurity region) 22 is shared between two memory cells that are adjacent to each other in the direction in which the bit line 14 extends. The bit line connection portion 14a or the plate line connection portion 16a may be configured so as not to be shared between two adjacent memory cells.

The gate electrode 12a, the ferroelectric film 18, the n-type drain region 20, the p-type source region 22, and the n-type channel region 24 form a ferroelectric field effect transistor (FeFET) having the ferroelectric film 18 as a gate insulating film. And this FeFET is an n-type tunnel field effect transistor (TFET) which has same conductive type (n-type) for both the drain region 20 and the channel region 24.

The semiconductor memory device according to this embodiment is a one-transistor (1T) non-volatile memory in which a memory cell includes one TFET.

Hereinafter, a method of operating the semiconductor memory device according to this embodiment will be described.

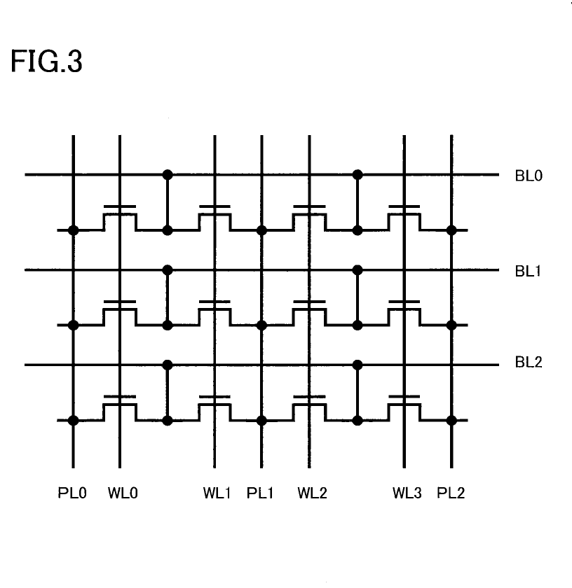

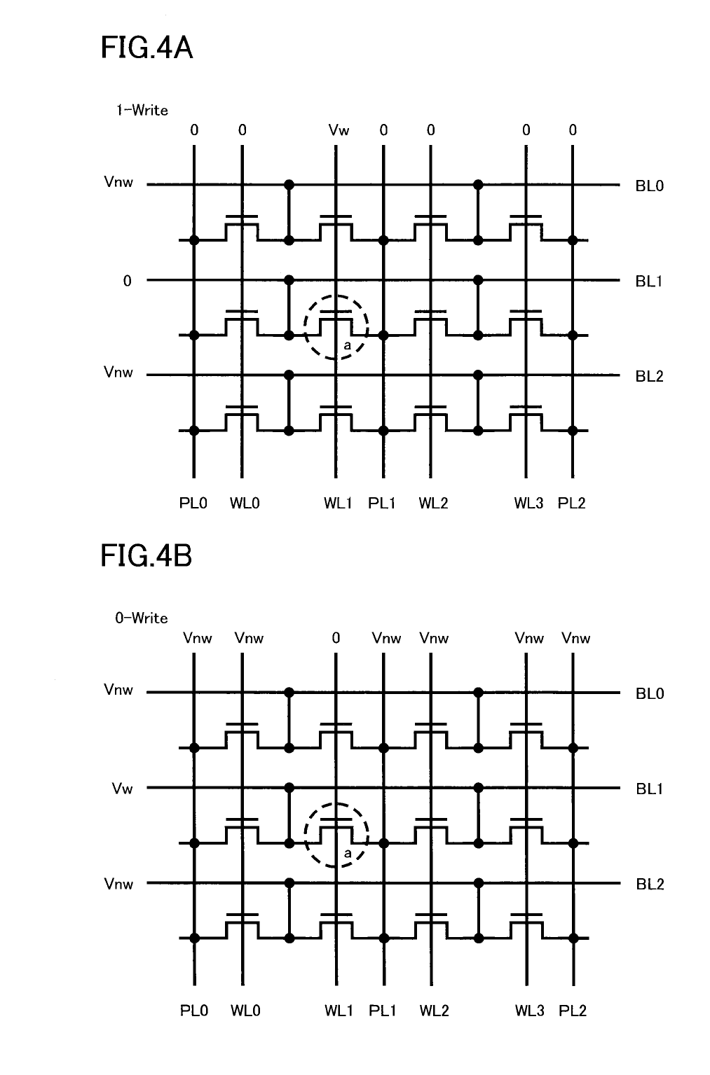

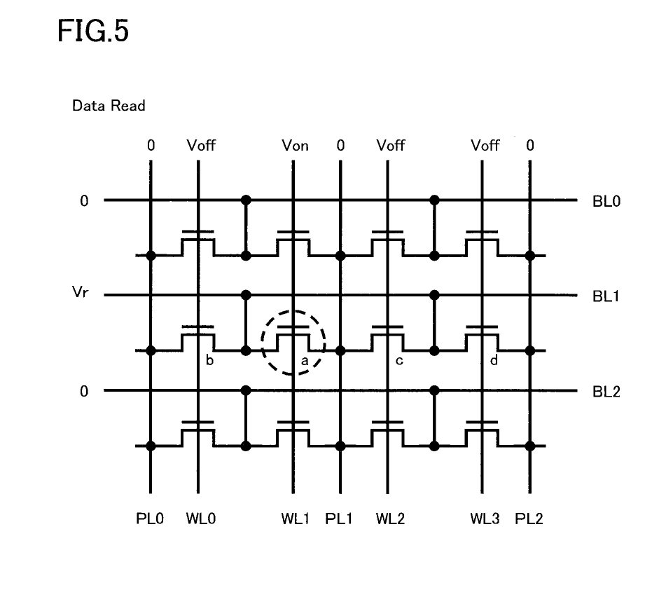

FIG. 3 is a circuit diagram illustrating the semiconductor memory device according to this embodiment. FIGS. 4A and 4B are diagrams illustrating a writing operation of the semiconductor memory device according to this embodiment. FIG. 5 is a diagram illustrating a reading operation of the semiconductor memory device according to this embodiment. In the drawings, a plurality of word lines (gate electrode lines) 12 are represented by WL0 to WL3, a plurality of bit lines (first wirings) 14 are represented by BL0 to BL2, and a plurality of plate lines (second wirings) 16 are represented by PL0 to PL2. In addition, in FIGS. 4A and 4B and FIG. 5, a selected memory cell (in the drawings, a memory cell a) to or from which data is written or read is represented by a dashed circle.

Hereinafter, data 1 is defined as a state in which the ferroelectric film is polarized such that a substrate side is positive and a gate electrode side is negative and the on-current of the TFET increases. In addition, data 0 is defined as a state in which the ferroelectric film is polarized such that the substrate side is negative and the gate electrode side is positive and the on-current of the TFET is reduced.

First, a data writing operation will be described. FIG. 4A illustrates a voltage applied to each line when data 1 is written. FIG. 4B illustrates a voltage applied to each line when data 0 is written.

When data is written to the selected memory cell, different voltages are applied to a bit line BL1 connected to the selected memory cell and a word line WL1 connected to the selected memory cell. The voltage difference is set to be more than a threshold voltage (polarization inversion threshold voltage) such that the polarization of the ferroelectric film is inverted.

When data 1 is written to the selected memory cell, a voltage of 0 V is applied to the bit line BL1 of the selected memory cell. A voltage Vw is applied to the word line WL1 of the selected memory cell. Therefore, the difference between the voltages applied to the ferroelectric film is Vw (=Vw−0 V). Vw is a voltage greater than the polarization inversion threshold voltage of the ferroelectric film. Here, Vw is a positive voltage.

A voltage Vnw is applied to bit lines other than the bit line BL1, that is, the bit lines BL0 and BL2. In addition, a voltage of 0 V is applied to word lines WL0, WL2, and WL3 other than the word line WL1. Then, a voltage of 0 V is applied to all of the plate lines PL0 to PL2.

The value of Vnw is less than that of Vw. The value of Vnw is set such that Vnw and Vw−Vnw are not greater than the polarization inversion threshold voltage of the ferroelectric film.

When the voltage of each wiring line is set as described above, the voltage Vw that is greater than the polarization inversion threshold voltage at which the gate electrode side is positive is applied to the ferroelectric film of the selected memory cell. Therefore, the ferroelectric film is polarized such that the substrate side is positive and the gate electrode side is negative and data 1 is written to the selected memory cell.

Only the voltage Vnw or Vw−Vnw that is not greater than the polarization inversion threshold voltage is applied to the ferroelectric film of the memory cells other than the selected memory cell, that is, non-selected memory cells. Therefore, data 1 is not written to the non-selected memory cell and data is not changed.

On the other hand, when data 0 is written to the selected memory cell, the voltage Vw is applied to the bit line BL1 of the selected memory cell. Then, a voltage of 0 V is applied to the word line WL1 of the selected cell. Therefore, the difference between the voltages applied to the ferroelectric film is Vw (=Vw−0 V).

A voltage Vnw is applied to bit lines other than the bit line BL1, that is, the bit lines BL0 and BL2. In addition, a voltage Vnw is applied to the word lines WL0, WL2, and WL3 other than the word line WL1. Then, the voltage Vnw is applied to all of the plate lines PL0 to PL2.

When the voltage of each wiring line is set as described above, the voltage Vw that is greater than the polarization inversion threshold voltage at which the gate electrode side is negative is applied to the ferroelectric film of the selected memory cell. Therefore, the ferroelectric film is polarized such that the substrate side is negative and the gate electrode side is positive and data 0 is written to the selected memory cell.

Only the voltage Vnw or Vw−Vnw that is not greater than the polarization inversion threshold voltage is applied to the ferroelectric film of the memory cells other than the selected memory cell, that is, non-selected memory cells. Therefore, data 0 is not written to the non-selected memory cell and data is not changed.

An appropriate combination of Vw and Vnw varies depending on, for example, a material forming the ferroelectric film and the thickness and characteristics of the ferroelectric film. For example, when a hafnium oxide film which has silicon added thereto (HfO:Si) and is formed under predetermined conditions is used as the ferroelectric film, Vw=6 V and Vnw=3 V can be applied.

Next, a data reading operation will be described with reference to FIG. 5.

When data is read from the selected memory cell, a voltage Von (third voltage) which turns on the transistor is applied to the word line WL1 connected to the selected memory cell. A voltage of 0 V (second voltage) is applied to the plate line PL1 connected to the selected memory cell and a voltage Vr (first voltage) is applied to the bit line BL1 connected to the selected memory cell.

The voltage difference between the word line WL1 and the plate line PL1 (the voltage difference between the third voltage and the second voltage) is Von (Von−0 V). Here, Von is set to a voltage that turns on the transistor, but does not invert the polarization of the ferroelectric film. That is, the voltage Von does not greater than the polarization inversion threshold voltage.

The voltage Vr (first voltage) is, for example, 0.3 V to 0.6 V. Since a voltage of 0 V (second voltage) is applied to the plate line PL1, the voltage Vr is the voltage difference between the bit line BL1 connected to the selected memory cell and the plate line PL1 connected to the selected memory cell. A current which flows between the bit line BL1 connected to the selected memory cell and the plate line PL1 connected to the selected memory cell, that is, the on-current of the transistor is detected to read data from the selected memory cell. A voltage applied between the bit line BL1 and the word line WL1 is not greater than the polarization inversion threshold voltage.

The magnitude of the on-current of the transistor depends on the polarization direction of the ferroelectric film. When data 1 is written, the on-current is more than that when data 0 is written since the threshold voltage of the transistor is reduced. A difference in the on-current is detected to determine whether the data is data 1 or data 0 and data is read from the selected memory cell.

Voff (fourth voltage) that is different from Von (third voltage) is applied to the word lines other than the word line WL1, that is, the word lines WL0, WL2, and WL3. In addition, a voltage of 0 V is applied to the bit lines other than the bit line BL1, that is, the bit lines BL0 and BL2. A voltage of 0 V (second voltage) is applied to the plate lines other than the plate line PL1, that is, the plate lines PL0 and PL2.

The voltage difference between the word lines WL0, WL2, and WL3 and the plate lines PL0 and PL2 (the voltage difference between the fourth voltage and the second voltage) is Voff (Voff−0 V). Voff is set to a voltage that does not turn on the transistor. Voff is, for example, 0 V or a negative voltage. Voff is set so as to have an absolute value at which the polarization of the ferroelectric film is not inverted. That is, Voff is set to a value that is not greater than the polarization inversion threshold voltage of the ferroelectric film.

When the voltage of each line is set as described above, the voltage Vr is applied between the source region and the drain region of the non-selected memory cells (in FIG. 5, memory cells b, c, and d) connected to the bit line BL1. Therefore, the absolute value of (Vr−Voff) is set such that the polarization of the ferroelectric film is not inverted. That is, (Vr−Voff) is set to a value that is not greater than the polarization inversion threshold voltage of the ferroelectric film.

When the voltage of each wiring line is set as described above, it is possible to read only data written to the selected memory cell, without rewriting data to the non-selected memory cells and reading data from the non-selected memory cells. In addition, the data of the selected memory cell is not changed. Therefore, an operation of rewriting data to the selected memory cell is not needed.

As described above, in the semiconductor memory device according to this embodiment, the voltage of the word line 12, the bit line 14, and the plate line 16 is controlled to write and read data to and from each memory cell.

Next, a method of manufacturing the semiconductor memory device according to this embodiment will be described with reference to FIGS. 1A to 1C and FIG. 2.

First, the device isolation region 26 is formed on the p-type semiconductor substrate 10. The device isolation region 26 is, for example, shallow trench isolation (STI) in which a trench is filled with a silicon oxide film. An active region which is separated by the device isolation region 26 is formed at the same time as the device isolation region 26 is formed.

A gate sacrifice insulating film is formed on the active region, by, for example, thermal oxidation. Then, n-type impurity ions are implanted to form the channel region 24. At that time, a p-well region that is deeper than the channel region 24 may be formed by the implantation of p-type impurity ions.

Then, the gate sacrifice insulating film is removed and the ferroelectric film 18 is formed. For example, a hafnium oxide (HfO) film, a zirconium oxide (ZrO) film, or an aluminum oxide (AlO) film is formed by a chemical vapor deposition (CVD) of atomic layer deposition (ALD) method. For example, impurities, such as silicon (Si) or yttrium (Y), are added to the hafnium oxide (HfO) film, the zirconium oxide (ZrO) film, or the aluminum oxide (AlO) film to control ferroelectricity.

Then, the gate electrode 12a is formed on the ferroelectric film 18. For example, a titanium nitride (TiN) film is formed on the ferroelectric film 18 by the CVD method. Then, an amorphous silicon (α-Si) film is formed on the titanium nitride (TiN) film by the CVD method. Then, a stacked film of TiN/α-Si is patterned to form the gate electrode 12a of the metal gate.

At an appropriate time after the formation of the TiN film, the formation of the α-Si film, and the processing of the gate electrode 12a, a heat treatment is performed to crystallize the ferroelectric film 18 such that the ferroelectric film 18 has ferroelectricity. For example, the time, temperature, and sequence of the heat treatment are appropriately adjusted in order to optimize device characteristics.

After the gate electrode 12a is formed, n-type impurity ions are implanted into the active region on one side of the gate electrode 12a to form the n-type drain region 20. In addition, p-type impurity ions are implanted into the active region on the other side of the gate electrode 12a to form the p-type source region 22. When the ion implantation processes are performed, for example, the boundary of a resist mask is provided on the gate electrode 12a to form the impurity regions of different conductivity types in the active regions on both sides of the gate electrode 12a.

Then, the plate line connection portion 16a, the plate line 16, the bit line connection portion 14a, and the bit line 14 are formed by a known manufacturing method.

The semiconductor memory device illustrated in FIGS. 1A to 1C and FIG. 2 is manufactured by the above-mentioned manufacturing method.

Next, a semiconductor memory device according to Comparative Example will be described. The semiconductor memory device according to Comparative Example differs from the semiconductor memory device according to this embodiment in that the transistor in the memory cell is an FET in which a source region and a drain region have the same conductivity type of impurities.

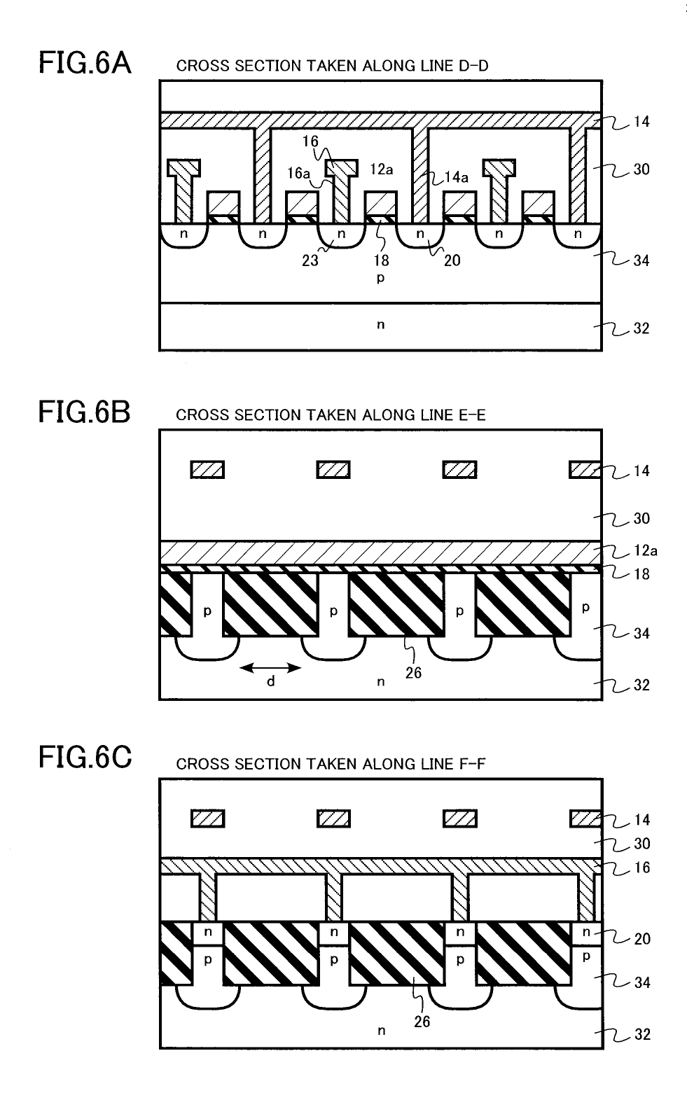

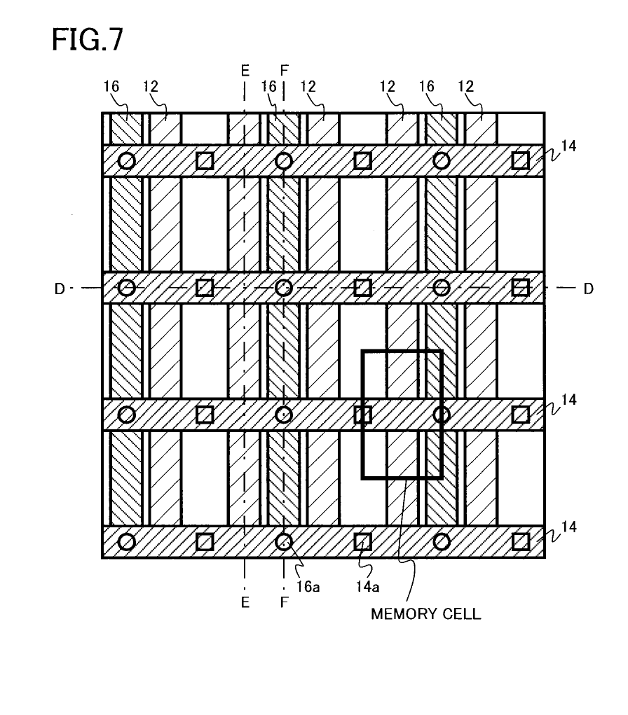

FIGS. 6A to 6C are cross-sectional views schematically illustrating the semiconductor memory device according to the comparative embodiment. FIG. 7 is a layout diagram illustrating the semiconductor memory device according to the comparative embodiment. FIG. 7 is a top view illustrating a region of a memory cell array. FIG. 6A is a cross-sectional view taken along the line D-D of FIG. 7, FIG. 6B is a cross-sectional view taken along the line E-E of FIG. 7, and FIG. 6C is a cross-sectional view taken along the line F-F of FIG. 7.

As illustrated in FIG. 7, a plurality of memory cells are arranged in a matrix. In FIG. 7, a region surrounded by a thick frame indicates a memory cell, that is, a unit cell.

In FIGS. 6A to 6C and FIG. 7, the same components as those in the first embodiment are denoted by the same reference numerals. Hereinafter, the description of the same structure as that in the first embodiment will not be repeated.

The semiconductor memory device according to Comparative Example includes an n-type source region 23, an n-type drain region 20, and a p-well region (channel region) 34. Therefore, the transistor in the memory cell is an n-type MISFET.

The p-well region 34 functions as a well line. The p-well regions (channel regions) 34 which are adjacent to each other in the direction in which a word line 12 extends are separated by an n-type semiconductor substrate (or an n well) 32. The separation distance of the p-well region 34 is represented by a distance d in FIG. 6B. In Comparative Example, circuit operation control factors are four since the well line is added. Therefore, the operation is complicated and Deep-Well needs to be introduced. As a result, a process for forming a deep implantation area needs to be added and a manufacturing process becomes complicated.

Next, a method of operating the semiconductor memory device according to Comparative Example will be described.

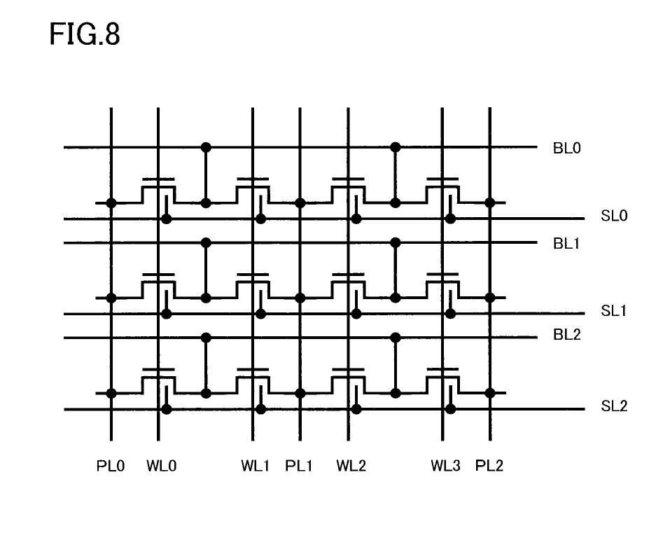

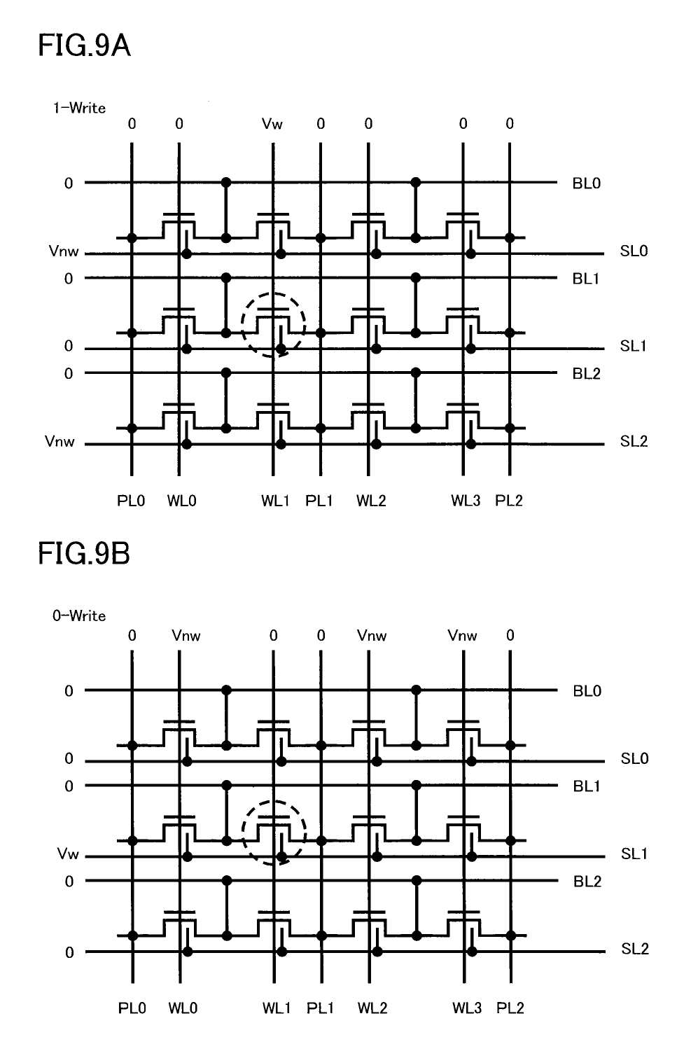

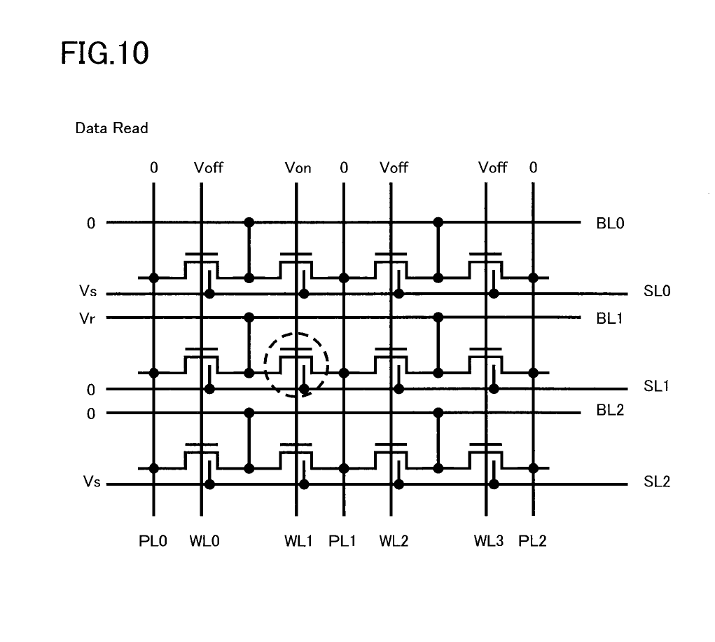

FIG. 8 is a circuit diagram illustrating the semiconductor memory device according to the comparative embodiment. FIGS. 9A and 9B are diagrams illustrating a writing operation of the semiconductor memory device according to the comparative embodiment. FIG. 10 is a diagram illustrating a reading operation of the semiconductor memory device according to the comparative embodiment. In the drawings, a plurality of word lines (gate electrode lines) are represented by WL0 to WL3, a plurality of bit lines (first wirings) are represented by BL0 to BL2, a plurality of plate lines (second wirings) are represented by PL0 to PL2, and a plurality of well lines are represented by SL0 to SL2. In addition, in FIGS. 9A and 9B and FIG. 10, a selected memory cell to or from which data is written or read is represented by a dashed circle.

First, a data writing operation will be described. FIG. 9A illustrates a voltage applied to each line when data 1 is written. FIG. 9B illustrates a voltage applied to each line when data 0 is written. In Comparative Example, a voltage difference is applied between the gate electrode 12a and the p-well region 34 to invert the polarization of the ferroelectric film.

When data 1 is written to the selected memory cell, a voltage Vw is applied to the word line WL1 connected to the selected memory cell. A voltage of 0 V is applied to the word lines other than the word line WL1 connected to the selected memory cell, that is, the word lines WL0, WL2, and WL3. A voltage of 0 V is applied to the well line SL1 connected to the selected memory cell. A voltage Vnw is applied to the well lines other than the well line SL1 connected to the selected memory cell, that is, the well lines SL0 and SL2. In addition, a voltage of 0 V is applied to all of the bit lines BL0 to BL2 and the plate lines PL0 to PL2.

The difference between the voltages applied to the ferroelectric film of the selected memory cell is Vw (=Vw−0 V). The voltage Vw is greater than the polarization inversion threshold voltage of the ferroelectric film. Here, Vw is a positive voltage. The value of Vnw is less than the value of Vw. The value of Vnw is set such that Vnw and Vw−Vnw are not greater than the polarization inversion threshold voltage of the ferroelectric film.

When the voltage of each wiring line is set as described above, the voltage Vw that is greater than the polarization inversion threshold voltage at which the gate electrode side is positive is applied to the ferroelectric film of the selected memory cell. Therefore, the ferroelectric film is polarized such that the substrate side is positive and the gate electrode side is negative and data 1 is written to the selected memory cell.

Only the voltage Vnw or Vw−Vnw that is not greater than the polarization inversion threshold voltage is applied to the ferroelectric film of the memory cells other than the selected memory cell, that is, non-selected memory cells. Therefore, data 1 is not written to the non-selected memory cell and data is not changed.

On the other hand, when data 0 is written to the selected memory cell, a voltage of 0 V is applied to the word line WL1 connected to the selected memory cell. The voltage Vnw is applied to the word lines other than the word line WL1 connected to the selected memory cell, that is, the word lines WL0, WL2, and WL3. The voltage Vw is applied to the well line SL1 connected to the selected memory cell. A voltage of 0 V is applied to the well lines other than the well line SL1 connected to the selected memory cell, that is, the well lines SL0 and SL2. In addition, a voltage of 0 V is applied to all of the bit lines BL0 to BL2 and the plate lines PL0 to PL2.

When the voltage of each wiring line is set as described above, the voltage Vw that is greater than the polarization inversion threshold voltage at which the gate electrode side is negative is applied to the ferroelectric film of the selected memory cell. Therefore, the ferroelectric film is polarized such that the substrate side is negative and the gate electrode side is positive and data 0 is written to the selected memory cell.

Only the voltage Vnw or Vw−Vnw that is not greater than the polarization inversion threshold voltage is applied to the ferroelectric film of the memory cells other than the selected memory cell, that is, non-selected memory cells. Therefore, data 0 is not written to the non-selected memory cell and data is not changed.

Next, a data reading operation will be described with reference to FIG. 10.

When data is read from the selected memory cell, a voltage Von which turns on the transistor is applied to the word line WL1 connected to the selected memory cell. A voltage of 0 V is applied to the plate line PL1 connected to the selected memory cell and a voltage Vr is applied to the bit line BL1 connected to the selected memory cell. A voltage of 0 V is applied to the well line SL1 connected to the selected memory cell.

A voltage Voff is applied to the word lines other than the word line WL1, that is, the word lines WL0, WL2, and WL3. A voltage of 0 V is applied to the bit lines other than the bit line BL1, that is, the bit lines BL0 and BL2. A voltage of 0 V is applied to the plate lines other than the plate line PL1, that is, the plate lines PL0 and PL2. A voltage Vs is applied to the well lines other than the well line SL1, that is, the well lines SL0 and SL2.

Here, Von is set to a voltage that turns on the transistor, but does not invert the polarization of the ferroelectric film. That is, the voltage Von is not greater than the polarization inversion threshold voltage. A voltage Voff is set to a value which does not turn on the transistor. Voff is, for example, 0 V or a negative voltage. The absolute value of the voltage Voff is set such that the polarization of the ferroelectric film is not inverted. That is, the voltage Voff is set to a value that is not greater than the polarization inversion threshold voltage of the ferroelectric film.

A voltage Vs is set such that the polarization of the ferroelectric film is not inverted by any of the voltage difference (potential difference) between Von and Vs and the voltage difference (potential difference) between Voff and Vs. That is, the voltage difference between both Vs to Von and Vs to Voff are set to a value that is not greater than the polarization inversion threshold voltage of the ferroelectric film.

When the voltage of each wiring line is set as described above, it is possible to read only data written to the selected memory cell, without rewriting data to the non-selected memory cells and reading data from the non-selected memory cells. In addition, the data of the selected memory cell is not changed. Therefore, an operation of rewriting data to the selected memory cell is not needed.

As described above, in the semiconductor memory device according to Comparative Example, the voltage of the word line 12, the bit line 14, the plate line 16, and the p-well region (well line) 34 is controlled to write and read data to and from each memory cell.

In the semiconductor memory device according to this embodiment, the TFET in which the drain region 20 and the channel region 24 are both n-type is used as the transistor of the memory cell. According to this structure, the polarization of the ferroelectric film 18 is inverted by the voltage applied between the gate electrode 12a and the drain region 20 to write data. In addition, according to this structure, it is possible to provide random access to each memory cell.

In the semiconductor memory device according to this embodiment, the voltage of the word line 12, the bit line 14, and the plate line 16 is controlled to provide random access to the memory cell. For example, a control operation using the well line is not needed, unlike Comparative Example. Therefore, the structure of the control circuit is simplified. In addition, an additional process for forming the well line is not needed. Therefore, a manufacturing process is simplified.

In this embodiment, the plate line (second wiring) 16 extends in the direction parallel to the word line 12. In addition, the bit line (first wiring) 14 extends in a direction perpendicular to the word line 12. According to this structure, the pitch between the bit lines (first wirings) 14 can be equal to the minimum pitch in the processing of the line. Therefore, the memory cell is miniaturized.

Furthermore, in this embodiment, the bit line connection portion 14a and the plate line connection portion 16a are shared by two memory cells. Therefore, the memory cell is miniaturized.

In this embodiment, since the TFET is used as the transistor, it is possible to perform a reading operation at a low voltage.

It is preferable that any one of a hafnium oxide (HfO) film, a zirconium oxide (ZrO) film, and an aluminum oxide (AlO) film with ferroelectricity be applied to the ferroelectric film 18 according to this embodiment. This is because these films are also used as a high-k insulating film of the transistor and have high consistency with a semiconductor process.

### Second Embodiment

A semiconductor memory device according to this embodiment differs from the semiconductor memory device according to the first embodiment in that a first wiring and a second wiring extend in a direction perpendicular to a gate electrode line. The description of the same structures as those in the first embodiment will not be repeated. For example, the description of the structure using a TFET and the operation thereof will not be repeated.

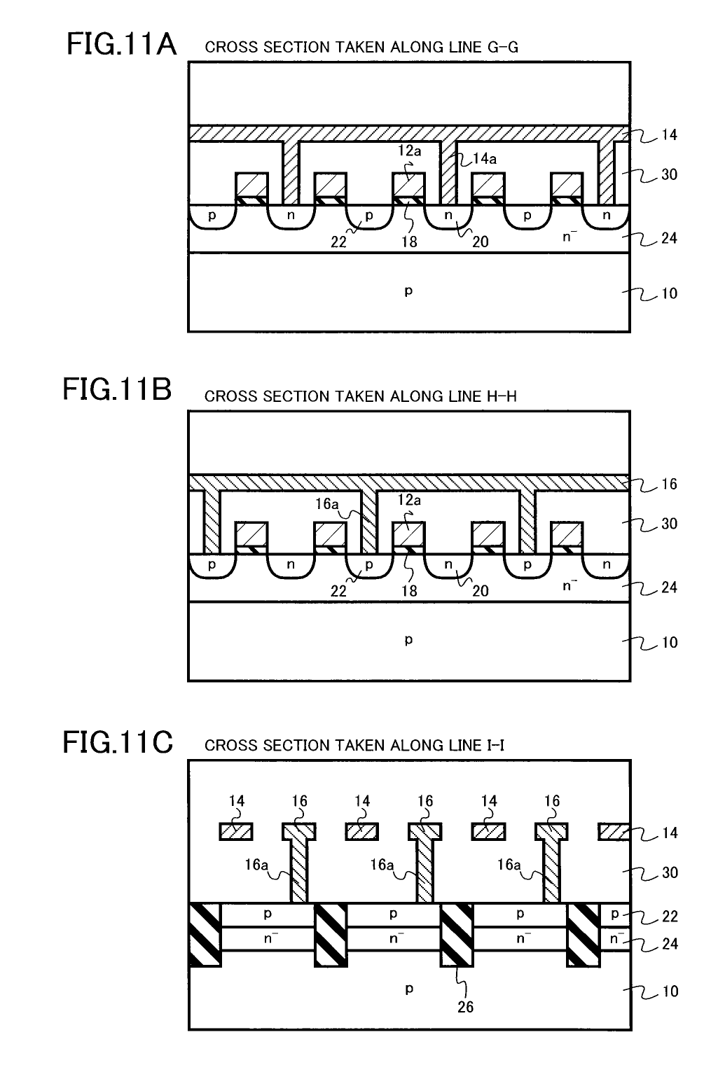

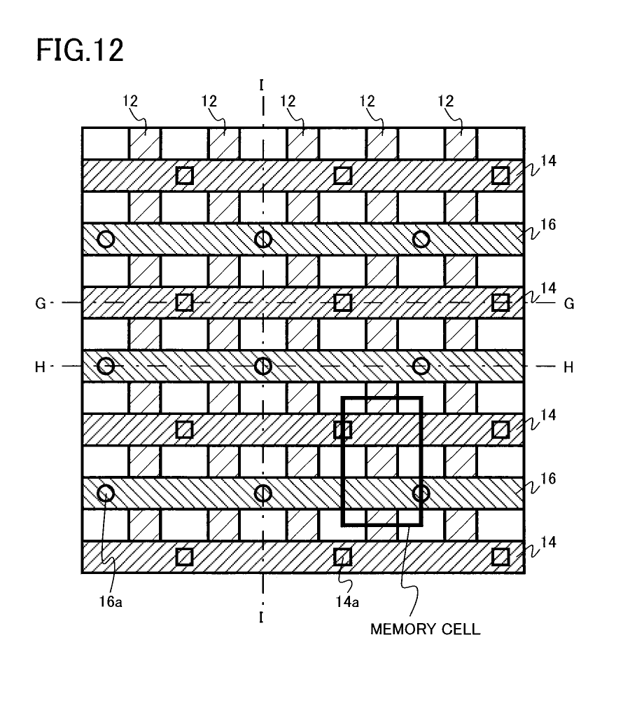

FIGS. 11A to 11C are cross-sectional views illustrating the semiconductor memory device according to this embodiment. FIG. 12 is a layout diagram illustrating the semiconductor memory device according to this embodiment. FIG. 12 is a top view illustrating a region of a memory cell array. FIG. 11A is a cross-sectional view taken along the line G-G of FIG. 12, FIG. 11B is a cross-sectional view taken along the line H-H of FIG. 12, and FIG. 11C is a cross-sectional view taken along the line I-I of FIG. 12.

As illustrated in FIG. 12, a plurality of memory cells are arranged in a matrix. In FIG. 12, a region surrounded by a thick frame is a memory cell, that is, a unit cell.

In FIGS. 11A to 11C and FIG. 12, the same components as those in the first embodiment are denoted by the same reference numerals. Hereinafter, the description of the same structure as that in the first embodiment will not be repeated.

The semiconductor memory device according to this embodiment includes a plurality of word lines (gate electrode lines) 12, a plurality of bit lines (first wirings) 14, and a plurality of plate lines (second wirings) 16. A predetermined voltage is applied to the gate electrode line 12, the bit line 14, and the plate line 16 in order to write, read, or erase data stored in each memory cell.

The bit line (first wiring) 14 and the plate line (second wiring) 16 extend in a direction perpendicular to the word line 12.

In the semiconductor memory device according to this embodiment, similarly to the first embodiment, as illustrated in FIGS. 11A to 11C and FIG. 12, a bit line connection portion 14a between the bit line (first wiring) 14 and a drain region (first impurity region) 20 is shared between two memory cells that are adjacent to each other in the direction in which the bit line 14 extends. In addition, a plate line connection portion 16a between the plate line (second wiring) 16 and a source region (second impurity region) 22 is shared between two memory cells that are adjacent to each other in the direction in which the bit line 14 extends. Therefore, the memory cell is miniaturized. However, the bit line connection portion 14a or the plate line connection portion 16a may be configured so as not to be shared.

Hereinafter, a method of operating the semiconductor memory device according to this embodiment will be described.

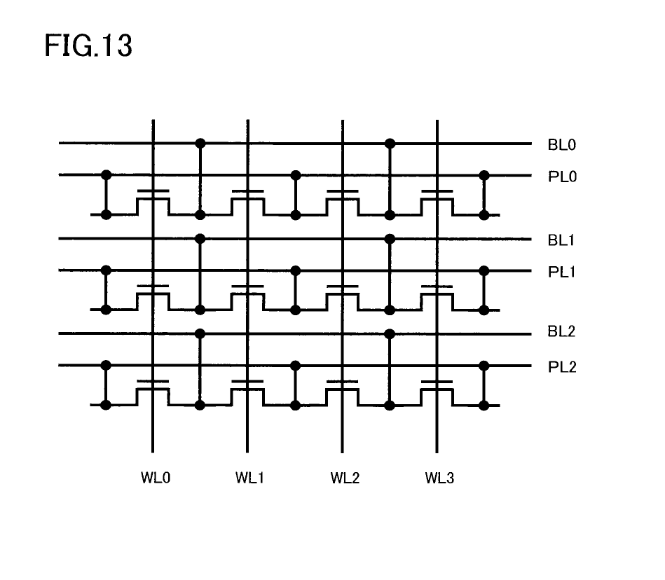

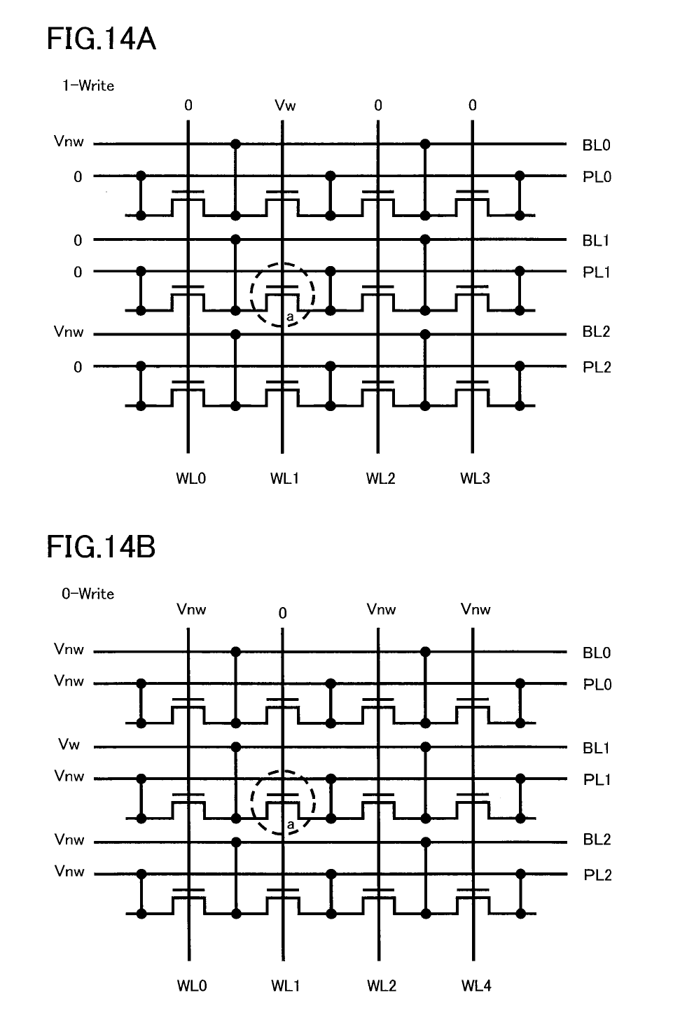

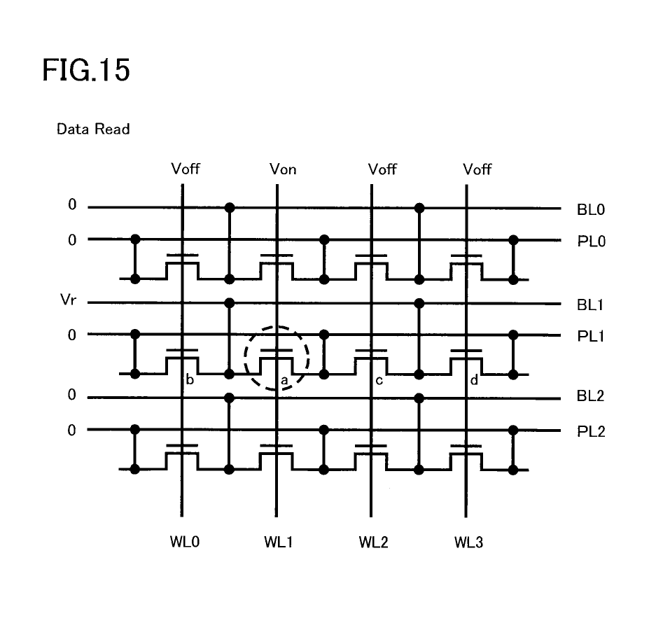

FIG. 13 is a circuit diagram illustrating the semiconductor memory device according to this embodiment. FIGS. 14A and 14B are diagrams illustrating a writing operation of the semiconductor memory device according to this embodiment. FIG. 15 is a diagram illustrating a reading operation of the semiconductor memory device according to this embodiment. In the drawings, a plurality of word lines (gate electrode lines) 12 are represented by WL0 to WL3, a plurality of bit lines (first wiring lines) 14 are represented by BL0 to BL2, and a plurality of plate lines (second wirings) 16 are represented by PL0 to PL2. In FIGS. 14A and 14B and FIG. 15, a selected memory cell (in the drawings, a memory cell a) to or from data is written or read is represented by a dashed circle.

This embodiment differs from the first embodiment in that the plate lines (second wirings) PL0 to PL2 intersect the word lines (gate electrode lines) WL0 to WL3, but is basically the same as the first embodiment in an operation method. Therefore, the detailed description of the operation method will not be repeated.

First, a data writing operation will be described. FIG. 14A illustrates a voltage applied to each line when data 1 is written. FIG. 14B illustrates a voltage applied to each line when data 0 is written.

When data 1 is written to the selected memory cell, a voltage of 0 V is applied to the bit line BL1 of the selected memory cell. Then, a voltage Vw is applied to the word line WL1 of the selected memory cell.

A voltage Vnw is applied to bit lines other than the bit line BL1, that is, the bit lines BL0 and BL2. In addition, a voltage of 0 V is applied to word lines WL0, WL2, and WL3 other than the word line WL1. Then, a voltage of 0 V is applied to all of the plate lines PL0 to PL2.

When the voltage of each line is set as described above, data 1 is written to the selected memory cell. In addition, since data 1 is not written to a non-selected memory cell, data is not changed.

On the other hand, when data 0 is written to the selected memory cell, the voltage Vw is applied to the bit line BL1 of the selected memory cell. Then, a voltage of 0 V is applied to the word line WL1 of the selected cell.

A voltage Vnw is applied to bit lines other than the bit line BL1, that is, the bit lines BL0 and BL2. In addition, a voltage Vnw is applied to the word lines WL0, WL2, and WL3 other than the word line WL1. Then, the voltage Vnw is applied to all of the plate lines PL0 to PL2.

When the voltage of each line is set as described above, data 0 is written to the selected memory cell. In addition, since data 0 is not written to the non-selected memory cell, data is not changed.

Next, a data reading operation will be described with reference to FIG. 15.

When data is read from the selected memory cell, a voltage Von which turns on the transistor is applied to the word line WL1 connected to the selected memory cell. A voltage of 0 V is applied to the plate line PL1 connected to the selected memory cell and a voltage Vr is applied to the bit line BL1 connected to the selected memory cell.

A voltage Voff is applied to the word lines other than the word line WL1, that is, the word lines WL0, WL2, and WL3. A voltage of 0 V is applied to the bit lines other than the bit line BL1, that is, the bit lines BL0 and BL2. A voltage of 0 V is applied to the plate lines other than the plate line PL1, that is, the plate lines PL0 and PL2.

When the voltage of each wiring line is set as described above, it is possible to read only data written to the selected memory cell, without rewriting data to the non-selected memory cells and reading data from the non-selected memory cells. In addition, the data of the selected memory cell is not changed.

In the semiconductor memory device according to this embodiment, similarly to the first embodiment, it is possible to provide random access to each memory cell with a simple structure. In addition, since the well line is not needed, it is possible to prevent a process from being complicated.

In this embodiment, since the bit line (first wiring) 14 and the plate line (second wiring) 16 both extend in the direction perpendicular to the word line 12, it is possible to form the bit line 14 and the plate line 16 in the same conductive layer. Therefore, a manufacturing process is further simplified.

### Third Embodiment

A semiconductor memory device according to this embodiment differs from the semiconductor memory device according to the first embodiment in that a semiconductor layer is a silicon-on-insulator (SOI) layer of an SOI substrate. The description of the same structures as those in the first embodiment will not be repeated. For example, the description of the structure using a TFET and the operation thereof will not be repeated.

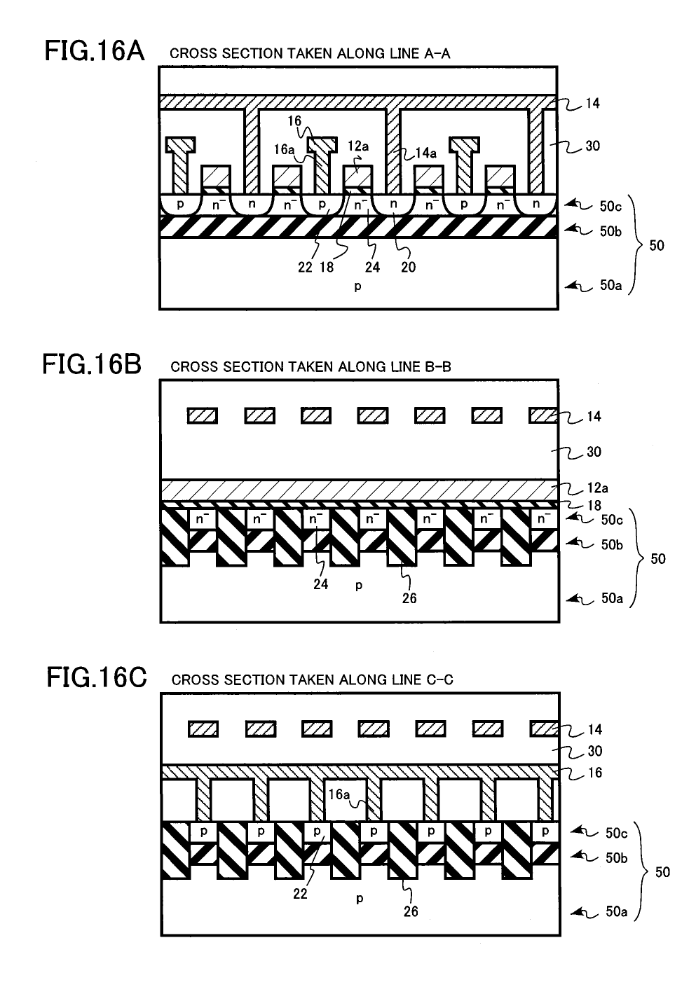

FIGS. 16A to 16C are cross-sectional views schematically illustrating the semiconductor memory device according to this embodiment. A memory cell has the same layout as that according to the first embodiment illustrated in FIG. 2. Therefore, the layout of the memory cell will be described with reference to FIG. 2 in this embodiment. FIG. 16A is a cross-sectional view taken along the line A-A of FIG. 2, FIG. 16B is a cross-sectional view taken along the line B-B of FIG. 2, and FIG. 16C is a cross-sectional view taken along the line C-C of FIG. 2.

In FIGS. 16A to 16C, the same components as those in the first embodiment are denoted by the same reference numerals. Hereinafter, the description of the same structure as that in the first embodiment will not be repeated.

The semiconductor memory device according to this embodiment is formed using an SOI substrate 50. The SOI substrate 50 includes a p-type substrate 50a, an insulating layer 50b, and an SOI layer 50c. An n-type drain region (first impurity region) 20, a p-type source region (second impurity region) 22, and an n-type channel region (third impurity region) 24 are formed in the SOI layer 50c.

In the semiconductor memory device according to this embodiment, similarly to the first embodiment, it is possible to provide random access to each memory cell with a simple structure. In addition, the memory cell is miniaturized.

When a general substrate is used, a forward bias is generated by the relationship between the voltage applied to the source and the drain and a substrate potential and a leakage current flows to the substrate. In order to solve the problem, it is necessary to control the substrate potential such that a reverse bias is applied. However, the use of the SOI substrate 50 makes it unnecessary to control the substrate potential. Therefore, it is easy to design a circuit. In addition, a manufacturing process is simplified.

### Fourth Embodiment

A semiconductor memory device according to this embodiment differs from the semiconductor memory device according to the first embodiment in that a semiconductor layer has a columnar shape and a gate electrode is provided around the semiconductor layer. The description of the same structures as those in the first embodiment will not be repeated. For example, the description of the structure using a TFET and the operation thereof will not be repeated.

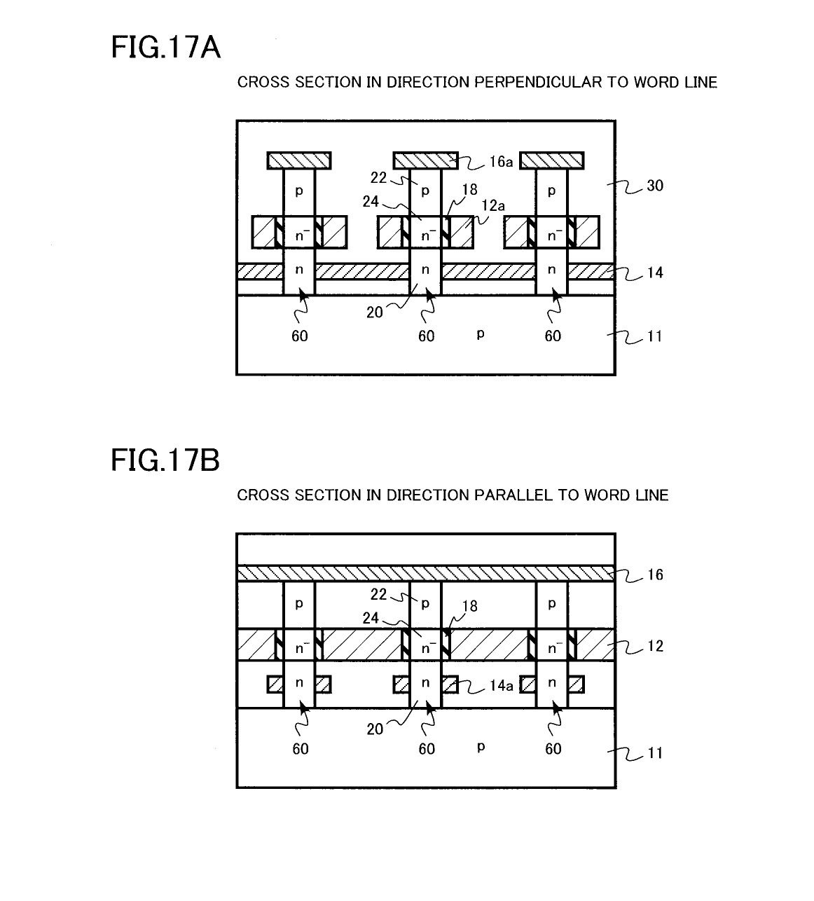

FIGS. 17A and 17B are cross-sectional views schematically illustrating the semiconductor memory device according to this embodiment. FIG. 17A is a cross-sectional view in a direction perpendicular to the direction in which a word line extends and FIG. 17B is a cross-sectional view in a direction parallel to the direction in which the word line extends.

In FIGS. 17A and 17B, the same components as those in the first embodiment are denoted by the same reference numerals. Hereinafter, the description of the same structure as that in the first embodiment will not be repeated.

A columnar semiconductor layer 60 is provided on a p-type semiconductor substrate 11. The columnar semiconductor layer 60 is made of, for example, single-crystal or polycrystalline silicon.

An n-type drain region (first impurity region) 20, a p-type source region (second impurity region) 22, and an n-type channel region (third impurity region) 24 are provided in the columnar semiconductor layer 60. Then, a ferroelectric film 18 and a gate electrode 12a are provided around the n-type channel region 24 of the columnar semiconductor layer 60.

In the semiconductor memory device according to this embodiment, a transistor of a memory cell is a vertical transistor. A bit line connection portion 14a comes into contact with the circumference of the n-type drain region 20 of the columnar semiconductor layer 60 and the n-type drain region 20 is connected to one of a plurality of bit lines (first wirings) 14 that extend in a direction perpendicular to the word line 12 through the bit line connection portion 14a. A plate line connection portion 16a comes into contact with the surface of the p-type source region 22 and the p-type source region 22 is connected to one of a plurality of plate lines (second wirings) 16 that extend in a direction parallel to the word line 12 through the plate line connection portion 16a.

The semiconductor memory device according to this embodiment can be basically manufactured by a known vertical transistor manufacturing method. When the columnar semiconductor layer 60 is formed, the n-type drain region (first impurity region) 20 and the n-type channel region (third impurity region) 24 are formed in a portion of the columnar semiconductor layer 60 close to the bit line 14 by, for example, the implantation of n-type impurity ions. In addition, the p-type source region (second impurity region) 22 is formed in a portion of the columnar semiconductor layer 60 close to the plate line 16 by the implantation of p-type impurity ions.

The semiconductor memory device according to this embodiment can be operated by the same sequence as that in the first embodiment.

In the semiconductor memory device according to this embodiment, similarly to the first embodiment, it is possible to provide random access to each memory cell with a simple structure. The vertical transistor structure makes it possible to further miniaturize the memory cell. In addition, the vertical transistor structure makes it easy to optimize a channel length.

### Fifth Embodiment

A semiconductor memory device according to this embodiment differs from the semiconductor memory device according to the first embodiment in that an active region of a memory cell extends at an angle that is more than 0 degree and less than 90 degrees with respect to a gate electrode line. The description of the same structures as those in the first embodiment will not be repeated. For example, the description of the structure using a TFET and the operation thereof will not be repeated.

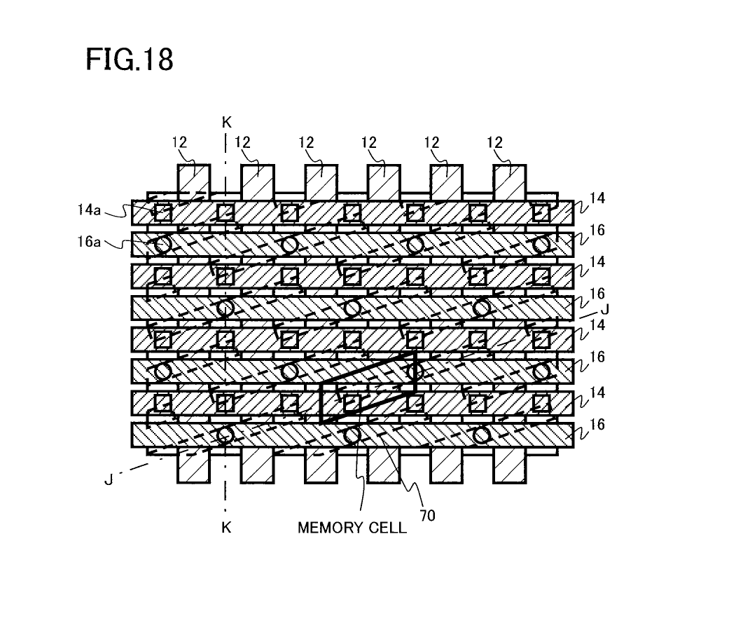

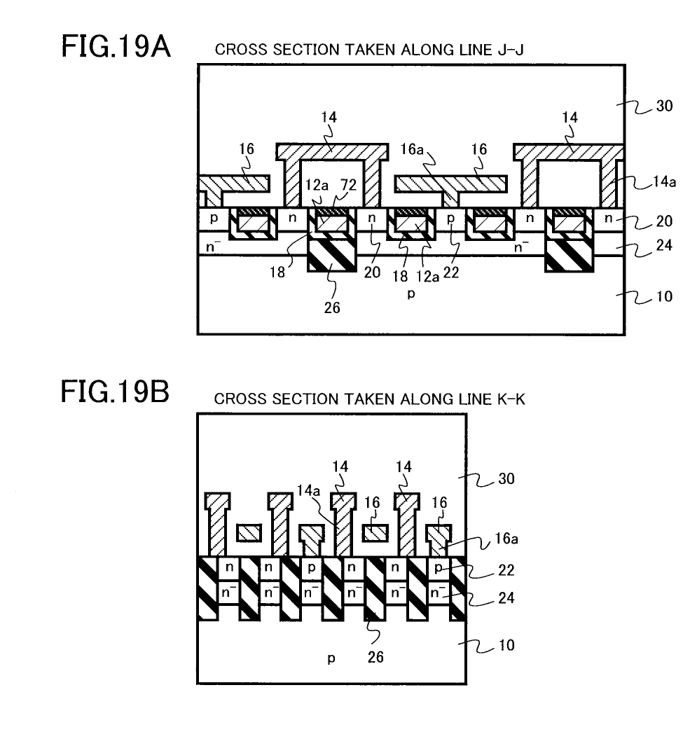

FIG. 18 is a layout diagram illustrating the semiconductor memory device according to this embodiment. FIGS. 19A and 19B are cross-sectional views schematically illustrating the semiconductor memory device according to this embodiment. FIG. 18 is a top view illustrating a region of a memory cell array. FIG. 19A is a cross-sectional view taken along the line J-J of FIG. 18 and FIG. 19B is a cross-sectional view taken along the line K-K of FIG. 18.

As illustrated in FIG. 18, a plurality of memory cells are arranged in a matrix. In FIG. 18, a region surrounded by a thick frame is a memory cell, that is, a unit cell.

In FIG. 18 and FIGS. 19A and 19B, the same components as those in the first embodiment are denoted by the same reference numerals. Hereinafter, the description of the same structure as that in the first embodiment will not be repeated.

As represented by a dotted line in FIG. 18, in the semiconductor memory device according to this embodiment, an active region 70 extends at an angle that is more than 0 degree and less than 90 degrees with respect to a gate electrode line 12. An n-type drain region (first impurity region) 20, a p-type source region (second impurity region) 22, and an n-type channel region (third impurity region) 24 are provided in the active region 70.

A ferroelectric film 18 and a gate electrode 12a are buried in a trench which is provided in a semiconductor substrate (semiconductor layer) 10. An etching stopper layer 72 which functions as an etching stopper when a contact hole of a bit line connection portion 14a or a plate line connection portion 16a is formed is provided on the gate electrode 12a. The etching stopper layer 72 is made of, for example, silicon nitride (SiN).

A region of the gate electrode 12a which functions as a transistor is buried in the active region 70. A region of the gate electrode 12a which does not function as the transistor is buried in an device isolation region 26.

The depth of the device isolation region 26 is more than that of the n-type channel region (third impurity region) 24.

Two memory cells which are formed in different active regions 70 and are adjacent to the direction in which the active region 70 extends are connected to the same bit line 14.

A plate line connection portion 16a connecting a plate line (second wiring) 16 and the source region (second impurity region) 22 is shared between two memory cells that are adjacent to each other in the direction in which the active region 70 extends and are formed in the same active region 70.

When the semiconductor memory device according to this embodiment is manufactured, first, the device isolation region 26 is formed on the p-type semiconductor substrate 10, similarly to the first embodiment. At that time, the active region 70 is patterned so as to extend at an angle that is more than 0 degree and less than 90 degrees with respect to the gate electrode line 12.

Then, the channel region 24 is formed by the implantation of n-type impurity ions. Then, the p-type semiconductor substrate 10 and the device isolation region 26 are etched to form a trench for burying the gate electrode 12a.

Then, the ferroelectric film 18 and the gate electrode 12a are buried in the trench and the etching stopper layer 72 is formed at the top of the trench.

Then, the drain region 20 and the source region 22 are formed in a portion of the active region 70 in which the gate electrode 12a is not buried and the contact hole of the plate line connection portion 16a is formed using the etching stopper layer 72 as an etching stopper. Then, the plate line 16 is formed. In addition, the contact hole of the bit line connection portion 14a is formed using the etching stopper layer 72 as an etching stopper. Then, the bit line 14 is formed.

The semiconductor memory device illustrated in FIG. 18 and FIGS. 19A and 19B is manufactured by the above-mentioned manufacturing method.

The semiconductor memory device according to this embodiment can be operated by the same sequence as that in the first and second embodiments.

In the semiconductor memory device according to this embodiment, similarly to the first embodiment, it is possible to provide random access to each memory cell with a simple structure. The layout in which the active region 70 is inclined with respect to the gate electrode line 12 makes it possible to further miniaturize a memory cell. That is, the packing density of memory cells is improved.

Even when the gate electrode 12a is not buried in the semiconductor substrate 10, it is possible to obtain the layout of the memory cells according to this embodiment.

It is preferable that the active region 70 extend at an angle that is equal to or more than 60 degrees and equal to or less than 80 degrees with respect to the gate electrode line 12, in order to improve the packing density of the memory cells.

In the first to fifth embodiments, the first conductivity type is n-type and the second conductivity type is p-type. However, the first conductivity type may be p-type and the second conductivity type may be n-type. And, in the comparative example, a transistor in the memory cell can be a p-type MISFET.

While certain embodiments have been described, these embodiments have been presented by way of example only, and are not intended to limit the scope of the inventions. Indeed, semiconductor memory device and a method of operating the same described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a semiconductor layer;
a gate electrode;
a ferroelectric film provided between the semiconductor layer and the gate electrode;
a first impurity region of a first conductivity type provided on one side of the gate electrode in the semiconductor layer;
a second impurity region of a second conductivity type provided on the other side of the gate electrode in the semiconductor layer;
a third impurity region of the first conductivity type provided between the first impurity region and the second impurity region in the semiconductor layer, the third impurity region facing the gate electrode and having a lower first-conductivity-type impurity concentration than the first impurity region;
a first wiring connected to the first impurity region through a first connection portion, the first connection portion contacting with the first impurity region; and
a second wiring connected to the second impurity region through a second connection portion, the second connection portion contacting with the second impurity region.

2. The device according to claim 1,
further comprising device isolation regions including insulators,
wherein the first impurity region, the second impurity region, and the third impurity region are interposed between the device isolation regions, and
the depth of the third impurity region is less than the depth of the device isolation regions.

3. The device according to claim 1,
wherein the semiconductor layer is an SOI layer of an SOI substrate.

4. The device according to claim 1,
wherein the semiconductor layer has a columnar shape, and
the gate electrode is provided around the semiconductor layer.

5. The device according to claim 1,
wherein a voltage is applied to the gate electrode to turn on a transistor, and
a voltage is applied between the first and second wirings such that a potential of the first wiring is constantly equal to or higher than a potential of the second wiring, thereby reading data.

6. The device according to claim 1,
wherein data is written by a voltage applied between the first wiring and the gate electrode.

7. A semiconductor memory device comprising:
a plurality of memory cells arranged in a matrix;
a plurality of gate electrode lines;
a plurality of first wirings; and
a plurality of second wirings,
wherein each of the memory cells includes,
a semiconductor layer,
a gate electrode connected to one of the gate electrode lines,
a ferroelectric film provided between the semiconductor layer and the gate electrode,
a first impurity region of a first conductivity type provided on one side of the gate electrode in the semiconductor layer, the first impurity region being connected to one of the first wirings through a first connection portion, the first connection portion contacting with the first impurity region,
a second impurity region of a second conductivity type provided on the other side of the gate electrode in the semiconductor layer, the second impurity region being connected to one of the second wirings through a second connection portion, the second connection portion contacting with the second impurity region, and
a third impurity region of the first conductivity type provided between the first impurity region and the second impurity region in the semiconductor layer, the third impurity region facing the gate electrode and having a lower first-conductivity-type impurity concentration than the first impurity region.

8. The device according to claim 7,
wherein the second wirings extend in a direction parallel to the gate electrode lines, and
the first wirings extend in a direction perpendicular to the gate electrode lines.

9. The device according to claim 7,
wherein the first wirings and the second wirings extend in a direction perpendicular to the gate electrode lines.

10. The device according to claim 7,
wherein the first connection portion contacting with the first impurity region is shared between two memory cells that are adjacent to each other in a direction in which the first wirings extend.

11. The device according to claim 7,
wherein the second connection portion contacting with the second impurity region is shared between two memory cells that are adjacent to each other in a direction in which the first wirings extend.

12. The device according to claim 7,
further comprising device isolation regions including insulators,
wherein the first impurity region, the second impurity region, and the third impurity region are interposed between the device isolation regions, and
the depth of the third impurity region is less than the depth of the device isolation regions.

13. The device according to claim 7,
wherein the semiconductor layer is an SOI layer of an SOI substrate.

14. The device according to claim 7,
wherein the semiconductor layer has a columnar shape, and
the gate electrode is provided around the semiconductor layer.

15. The device according to claim 7,
wherein when data is read from a selected memory cell that is selected from the plurality of memory cells,
a voltage is applied to a gate electrode of the selected memory cell to turn on a transistor, and
a voltage is applied between one of the first wirings connected to the selected memory cell and one of the second wirings connected to the selected memory cell such that a potential of the one of the first wirings is constantly equal to or higher than a potential of the one of the second wirings.

16. The device according to claim 7,
wherein data is written by a voltage applied between one of the first wirings and one of the gate electrode lines.

17. A method of operating a semiconductor memory device including a plurality of memory cells arranged in a matrix, a plurality of gate electrode lines, a plurality of first wirings, and a plurality of second wirings,
each of the memory cells including a semiconductor layer, a gate electrode connected to one of the gate electrode lines, a ferroelectric film provided between the semiconductor layer and the gate electrode, a first impurity region of a first conductivity type provided on one side of the gate electrode in the semiconductor layer and connected to one of the first wirings, a second impurity region of a second conductivity type provided on the other side of the gate electrode in the semiconductor layer and connected to one of the second wirings, and a third impurity region of the first conductivity type provided between the first impurity region and the second impurity region in the semiconductor layer so as to face the gate electrode and having a lower first-conductivity-type impurity concentration than the first impurity region, the operating method comprising:
when data is read from a selected memory cell that is selected from the plurality of memory cells,
applying a first voltage to one of the first wirings connected to the selected memory cell,
applying a second voltage different from the first voltage to one of the second wirings connected to the selected memory cell;
applying a third voltage different from the second voltage to one of the gate electrode lines connected to the selected memory cell such that a transistor of the selected memory cell is turned on; and
detecting an electric current flowing between the one of the first wirings and the one of the second wirings.

18. The method according to claim 17,
further comprising when data is written to the selected memory cell,
applying voltages to the gate electrode lines and the first wirings such that a voltage between the one of the first wirings and the one of the gate electrode lines connected to the selected memory cell is greater than a polarization inversion threshold voltage of the ferroelectric film and a voltage between one of the first wirings and one of the gate electrode lines connected to a non-selected memory cell other than the selected memory cell is not greater than the polarization inversion threshold voltage of the ferroelectric film.

19. The method according to claim 17,
wherein when data is read from the selected memory cell, a voltage that does not turn on a transistor of a non-selected memory cell is applied to an another gate electrode line connected to the non-selected memory cell, the another gate electrode line being one of the gate electrode lines other than the one of the gate electrode lines connected to the selected memory cell, and
voltages of the first wirings are set such that a potential difference between a gate electrode and a first impurity region of the selected memory cell and a potential difference between a gate electrode and a first impurity region of the non-selected memory cell are not greater than the polarization inversion threshold voltage of the ferroelectric film.

20. The method according to claim 17,
wherein each of a first impurity region of the selected memory cell and a first impurity region of non-selected memory cell other than the selected memory cell is applied with a voltage of one of the first wirings.
